(19) United States
(12) Patent Application Publication
(10) Pub. No.: US 2018/0323138 A1
(43) Pub. Date: Nov. 8, 2018

(54) REDUNDANT THROUGH-HOLE INTERCONNECT STRUCTURES

(71) Applicant: Intel Corporation, Santa Clara, CA (US)

(72) Inventors: Amanda E. SCHUCKMAN, Chandler, AZ (US); Sri Ranga Sai BOYAPATI, Chandler, AZ (US); Maroun D. MOUSSALLEM, Solon, OH (US)

(21) Appl. No.: 15/772,682

(22) PCT Filed: Dec. 23, 2015
(86) PCT No.: PCT/US2015/000491

§ 371 Date: May 1, 2018

(51) Int. Cl. H01L 23/498; H01L 21/48; H01L 23/00

(52) U.S. Cl. CPC H01L 23/49827; H01L 21/486; H01L 23/49822; H01L 2924/15311; H01L 24/16; H01L 24/81; H01L 2224/16225; H01L 23/49894

(57) ABSTRACT

Techniques and mechanisms for efficiently providing reliable connection through a substrate such as that of a core of a packaged integrated circuit device. In an embodiment, a substrate has formed therein a through-hole interconnects, wherein an insulator is disposed between the through-hole interconnects in the substrate. A redundant configuration of the through-hole interconnects with respect to each other allows for a higher tolerance of voids being formed in the through-hole interconnects. In another embodiment, the through-hole interconnects are shorted together at one side of the substrate, and are further shorted together at an opposite side of the substrate. A total volume of any voids formed by one of the through-hole interconnects is equal to or more than six thousand cubic micrometers.

### BACKGROUND

### 1. Technical Field

Embodiments of the invention relate generally to the field of microelectronic processing and more particularly, but not exclusively, to methods of forming redundant via structures in a substrate.

### 2. Background Art

Electrical performance of an interconnect structure, such as one including a filled through-hole with conductive material in a core substrate, may be adversely affected by undesired electrical resistivity of the interconnect structure resulting from deficiencies in manufacturing such an interconnect structure. For example, a laser etched through-hole may potentially have high wall roughness, asymmetrical shape with dimensional variations, and misalignments at the top and bottom diameter of the through-hole. A combination of these factors may result in voids when filling the through-hole with a conductive material (e.g., by plating copper) to form an interconnect structure. The formation of voids may lead to reduced current carrying capability of the interconnect structure.

As stacking and other types of integration of circuitry in packaged devices continue to scale, there is increasing demand for providing reliable connectivity in core substrates of such packaged devices.

### BRIEF DESCRIPTION OF THE DRAWINGS

The various embodiments of the present invention are illustrated by way of example, and not by way of limitation, in the figures of the accompanying drawings and in which:

FIG. 1 is a cross-sectional view illustrating elements of interconnect structures to provide connection through a substrate according to an embodiment.

FIG. 2 is a flow diagram illustrating elements of a method to form interconnect structures in a substrate according to an embodiment.

FIG. 3 is a cross-sectional view illustrating elements of interconnect structures to provide connection through a substrate according to an embodiment.

FIG. 4 is a cross-sectional view of an integrated circuit device including of interconnect structures according to an embodiment.

FIG. 5 shows perspective views of interconnect structures to provide connection through a substrate according to an embodiment.

FIG. 6 is a functional block diagram illustrating an exemplary computer system, in accordance with one embodiment.

FIG. 7 is a functional block diagram illustrating an exemplary computer device, in accordance with one embodiment.

### DETAILED DESCRIPTION

Embodiments discussed herein variously include techniques and/or mechanisms for providing electrical connection through a substrate such as that of a core included in, or to be included in, a packaged integrated circuit device. In some embodiments, two or more hole structures (referred to herein a “through-holes”) each extend from one side of a substrate through to a second side of the substrate, where an insulation material is disposed between the two or more holes within the substrate, but where respective interconnects disposed in the through-holes are coupled with one another both at the first side and the second side. As used herein, “through-hole interconnect” refers to a conductive structure, formed within a through-hole, which enables electrical coupling through the substrate in which the through-hole is formed. Unless otherwise indicated, “redundant” is used herein to refer to the characteristic of multiple distinct through-hole interconnects, that each extend through a substrate, being coupled (e.g., shorted) to one another at both of two opposite sides of that substrate. For example, one through-hole interconnect may be redundant to another through-hole interconnect where the two through-hole interconnects are coupled to each other at both of two opposite sides of a substrate. The two through-hole interconnects together may be referred to as a “redundant through-hole interconnect pair.”

One problem with through-hole interconnects is the inclusion and/or formation of voids therein (where “void,” in this context, refers to a region where no conductive material is present). Instead of copper or some other conductor, a void may include a gas (e.g., air) or liquid (e.g., electrolytic Cu plating solution) that reduces the overall conductive characteristics of a through-hole interconnect. Ultra-thin core (UTC) devices, which typically include cores that are equal to or less than 250 micrometers (μm) are just one example of a technology that typically imposes stringent requirements with respect to the acceptable total volume of any voids within a through-hole interconnect. Meeting these void requirements often requires relatively slow and/or more expensive metal deposition processing.

Certain embodiments result from a realization that a redundant through-hole interconnect may provide an opportunity to exploit metal deposition processes that, in the absence of such a redundant through-hole interconnect, might be inadequate to meet a void specification. The inclusion of a redundant through-hole interconnect is undesirable at least with respect to a decreased efficiency in space utilization. However, this space inefficiency may, at least in some circumstances, be offset by gains made with faster and/or cheaper metal deposition processes. Additional or alternative gains may include faster and/or cheaper sampling and testing during the manufacturing process.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices including a substrate and redundant through-hole interconnect structures formed therein and/or thereon. Certain features of various embodiments are described herein with reference to the formation of redundant through-hole interconnects in a substrate of a core. However, such description may be extended to additionally or alternatively apply to the formation of through-hole interconnects in any of a variety of other substrates.

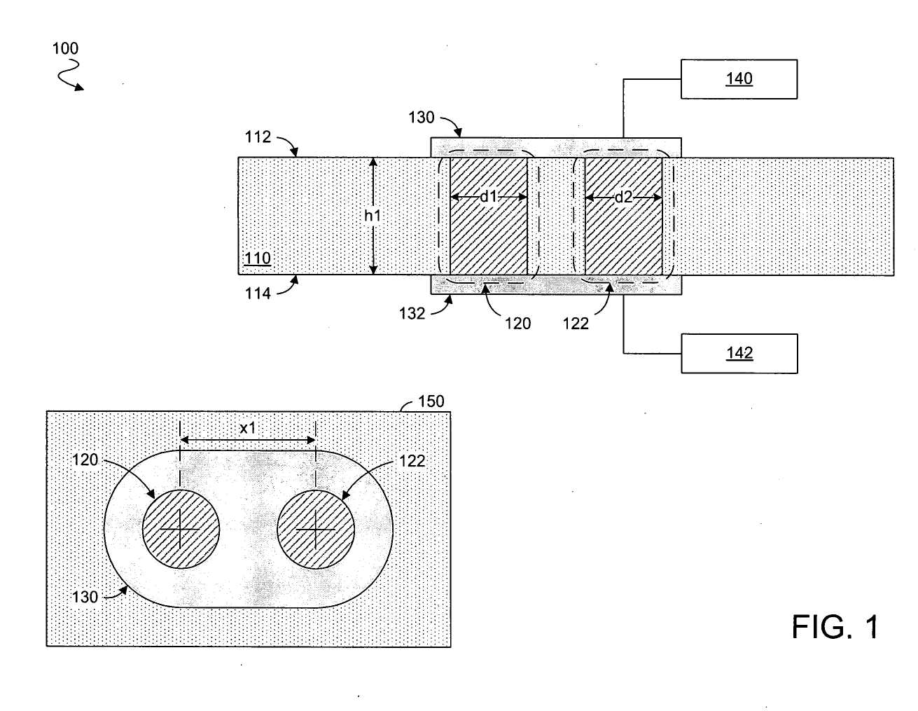

FIG. 1 shows features of a device 100 including through-hole interconnect structures according to an embodiment. Device 100 is one example of an embodiment that includes two or more through-holes interconnects that are coupled to one another both at one side of a substrate and at an opposite side of the substrate. Some of all of such two or more through-holes interconnects may each have formed therein one or more voids—e.g., wherein a total volume of such one or more voids is indicative of metallization processing that might otherwise not be sufficient, in the absence of redundant through-hole interconnect structures.

In the illustrative embodiment shown, device 100 includes a substrate 100 having formed therein a through-hole interconnect 120 and a through-hole interconnect 122 each extending from a first side 112 of substrate 110 to a second side 114 of substrate 110 that is opposite side 112. Substrate 110 may include any of a variety of insulator materials that, for example, are used in cores of conventional IC devices. For example, substrate 110 may include an epoxy, resin and/or a glass. In one embodiment, substrate 100 forms a monolithic core structure. Alternatively, substrate 100 may include multiple layers (not shown) of a laminate core. In some embodiments, substrate 110 includes a dielectric material that defines at least in part—e.g., that adjoins and surrounds—one or both of the respective through-holes for through-hole interconnects 120, 122. In such an embodiment, substrate 110 may further comprise one or more other materials—e.g., including a semiconductor such as silicon—that are isolated from one or both of through-hole interconnects 120, 122 by the dielectric material.

Formation of through-hole interconnects 120, 122 may include the formation of respective through-holes between sides 112, 114—e.g., using operations adapted from convention laser etching and/or other such techniques. Such formation may further comprise deposition of conductive material in such through-holes. For example, copper and/or another metal (e.g., including an alloy) may be plated or otherwise deposited by operations adapted from any of a variety of conventional metallization techniques. Some examples of such techniques include, but are not limited to, paste printing, electroless deposition and vapor deposition.

One or more dimensions of device 100 may result in a significant risk of voids affecting the connectivity provided by a given through-hole interconnect. For example, a total volume of one through-hole in substrate 110 may be equal to or less than twenty million (20·10⁶) cubic microns (μm³). In some embodiments, a total volume of a through-hole is equal to or less than thirteen million (13·10⁶) μm³—e.g., wherein the total volume of a through-hole is equal to or less than three and a half million (3.5·10⁶) μm³. In an illustrative scenario according to one embodiment, substrate 110 has a thickness hl that is equal to or less than 400 μm, where a width of a through-hole interconnect—e.g., a diameter d1 of through-hole interconnect 120 or a diameter d2 of through-hole interconnect 120—is equal to or less than 200 μm. In such a scenario, one of through-hole interconnects 120, 122 may be susceptible to the formation of voids that affect that interconnect's reliability in providing electrical connection across substrate 110.

To improve the operational reliability of device 100, some embodiments compensate for the risk of voids (for example, increase a tolerance of voids) by including a through-hole interconnect that is redundant to another through-hole interconnect. For example, in a region between sides 112, 114, through-hole interconnects 120, 122 may be separated from one another (and at least partially electrically isolated from one another) by an insulator material of substrate 110. However, through-hole interconnects 120, 122 may be coupled to one another at side 112 and further coupled to one another at side 114. By way of illustration and not limitation, an interconnect structure 130 may provide a short between through-hole interconnects 120, 122 at side 112. Alternatively or in addition, an interconnect structure 132 may provide a short between through-hole interconnects 120, 122 at side 114. Interconnect structure 130 and/or interconnect structure 132 may comprise any of a variety of conductive pads, traces or the like. Interconnect structure 130 (or interconnect structure 132) may include a single pad, two or more smaller pads connected and a trace coupled between such pads, two or more smaller pads coupled at a tangent to each other, or the like. Formation of interconnect structures 130, 132 may include operations adapted from conventional metallization techniques to form metal (e.g., copper) pads, bumps, traces or other such structures. In some embodiments, interconnect structure 130 is at least partially disposed within substrate 110 at side 112 and/or interconnect structure 132 is at least partially disposed within substrate 110 at side 114.

A proximity of a through-hole interconnect to its respective redundant through-hole interconnect may mitigate a reduction in space utilization. For example, a pitch x1 between through-hole interconnects 120, 122 may be equal to or less than 300 μm (e.g., where x1 is less than or equal to 200 μm). Alternatively or in addition, respective cross-sections of redundant through-hole interconnects—e.g., the cross-sections of through-hole interconnects 120, 122 that are shown in detail view 150—may be 100 μm or less apart from one another in a plane that extends between and/or in parallel with sides 112, 114.

In some situations, the use of two redundant through-hole interconnects may be a more efficient solution—e.g., in at least one dimension of space utilization—for obtaining the same tolerance for void formation as that provided by a single, larger through-hole interconnect that has no redundant counterpart. This may be the case, for example, where void formation does not scale linearly with one or more of a volume, cross-sectional area, width and length of a through-hole.

The reduction in space utilization (resulting from redundant through-hole interconnect structures) may be further offset, according to one embodiment, by an availability of metallization processes that might otherwise be insufficient for reliable operation of a single through-hole interconnect that has no redundant through-hole interconnect counterpart. For example, some embodiments may include performing metallization processing that allows for a somewhat high void volume in one through-hole interconnect, where the risk of such a void volume is compensated for by the presence of a redundant through-hole interconnect. By way of illustration and not limitation, a total volume of any voids in one of through-hole interconnects 120, 122 may be equal to or more than six thousand (6·10³) μm³. For example, such a total volume of any voids is equal to or more than nine thousand (9·10³) μm³—e.g., where the total volume is equal to or more than twelve thousand (12·10³) μm³. In some embodiments, the total volume of any voids in a through-hole interconnect is equal to or more than fifteen thousand (15·10³) μm³. Some embodiments variously allow for relatively fast and/or cheap metallization processes, and exploit a very low likelihood that both interconnects of a through-hole interconnect pair would fail.

In an embodiment, device 100 includes, or is coupled to, one or more circuits that are to participate in an exchange of a signal, a supply voltage and/or the like. The exchange may be a unidirectional or bidirectional exchange using through-hole interconnects 120, 122. By way of illustration and not limitation, through-hole interconnects 120, 122 may be coupled to a circuit 140 via a path through side 112, and further coupled to another circuit 142 via a path through side 114. In one embodiment, a build-up layer (not shown) of device 100 is coupled to substrate 110 at one of sides 112, 114, where circuit 140 or circuit 142 is included in such a build-up layer or, alternatively, is coupled to substrate 110 via the build-up layer. One of circuits 140, 142 may include a voltage regulator or other such circuitry that is to provide a supply voltage to the other of circuits 140, 142. However, some embodiments are not limited with respect to a particular functionality of one or both of circuits 140, 142 and/or with respect to a particular exchange that is might be performed with through-hole interconnects 120, 122.

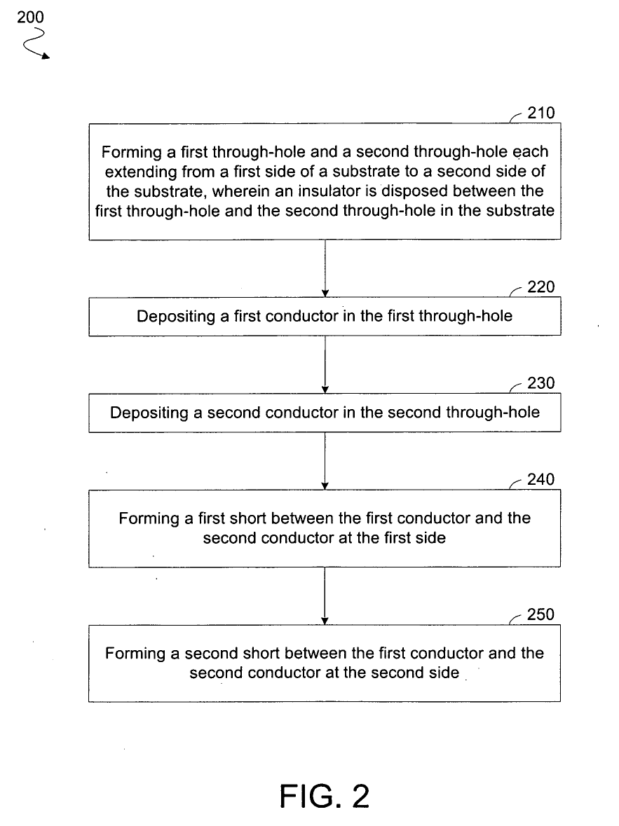

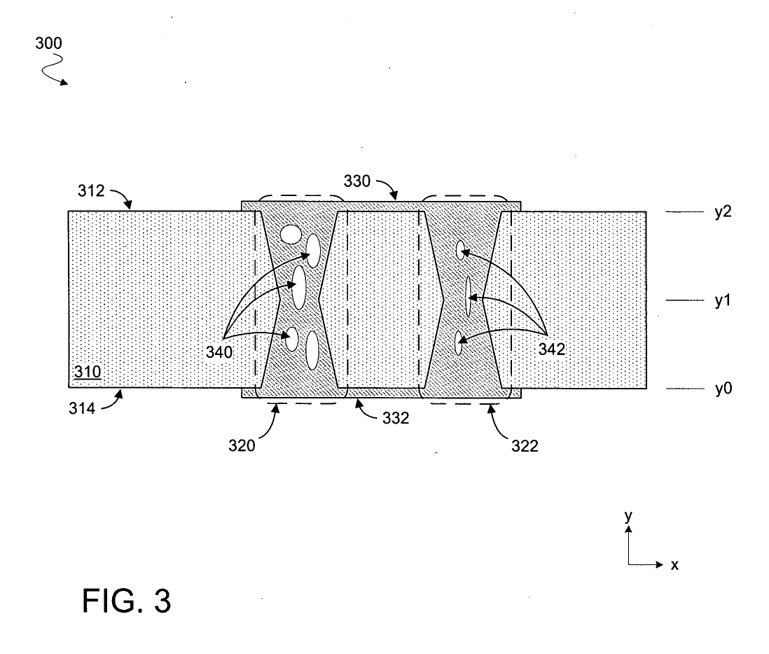

FIG. 2 shows features of a method 200 to fabricate redundant through-hole interconnect structures according to an embodiment. Method 200 may include operations to fabricate device 100, for example. To illustrate certain features of various embodiments, method 200 is described herein with reference to the manufacture of a device 300 shown in FIG. 3. However, such description may be extended to apply to any of a variety of additional or alternative devices, according to different embodiments.

In an embodiment, method 200 includes, at 210, forming a first through-hole and a second through-hole each extending from a first side of a substrate to a second side of the substrate, wherein an insulator is disposed between the first through-hole and the second through-hole in the substrate. Method 200 may further comprise, at 220, depositing a first conductor in the first through-hole and, at 230, depositing a second conductor in the second through-hole. The depositing at 220 and the depositing at 230 may be performed with a single plating or other metallization process, for example.

In the example embodiment of device 300, operations 210, 220 and 230 of method 200 result in through-hole interconnects 320, 322 that variously extend each from a side 312 of a substrate 310 (such as substrate 110) to a side 314 that is opposite side 312. For example, formation of the respective through-holes for through-hole interconnects 320, 322 may include performing first laser etching through side 312 to form holes that each extend from a plane y2 to a plane y1 within substrate 310. Additional etching through side 314 may form holes that variously extend from a plane y0 at side 314 each to join with a respective one of the holes formed by the first laser etching. Due to such laser etching, a width of through-hole interconnect 320 and/or a width of through-hole interconnect 322 may vary across the thickness of substrate 310. By way of illustration and not limitation, one of through-hole interconnects 320, 322 may have a width (e.g., diameter) of 100 μm at one of planes y0, y2, and a width at plane y1 that is less than 100 μm—e.g., between 45 μm and 70 μm. However, such dimensions are merely illustrative, and may vary widely in different embodiments, according to implementation-specific details.

Method 200 may further comprise, at 240, forming a first short between the first conductor and the second conductor at the first side. For example, metal deposition in or on side 312 may form an interconnect structure 330 that shorts together respective ends of through-hole interconnects 320, 322. In an embodiment, method 200 further includes forming, at 250, a second short between the first conductor and the second conductor at the second side. The forming at 250 may include depositing a conductor in or on side 314 to form an interconnect structure 332 that shorts together other respective ends of through-hole interconnects 320, 322. The depositing at 220 and at 230 may include or otherwise allow for the formation of one or more voids 340 in through-hole interconnect 320 and/or the formation of one or more voids 342 in through-hole interconnect 322.

In an illustrative scenario according to one embodiment, a total volume of the one or more voids 340 (e.g., all voids of through-hole interconnect 320) or a total volume of the one or more voids 342 (e.g., all voids of through-hole interconnect 322) is equal to or more than 6·10³ μm³. In such an embodiment, the total volume of the one or more voids 340 or the total volume of the one or more voids 340 is less than some threshold maximum amount—e.g. seventeen thousand (17·10³)μm³—that still allows for reliable operation of the redundant through-hole interconnect pair 320, 322 as a whole. Such a threshold maximum amount may be greater where, in one embodiment, more than two through-hole interconnects are all redundant to each other. For example, in some embodiments, method 200 may include further one or more additional through-hole interconnects (not shown), where interconnect structures 330, 332 and/or additional interconnect structures short the one or more additional through-hole interconnects with interconnect structures 330, 332 both at side 312 and at side 314. In such a scenario, the total volume of voids in any one of the three (or more) redundant through-hole interconnects may be more than seventeen thousand (17·10³) μm³—e.g., where such a total volume is more than twenty thousand (2·10⁴)μm³.

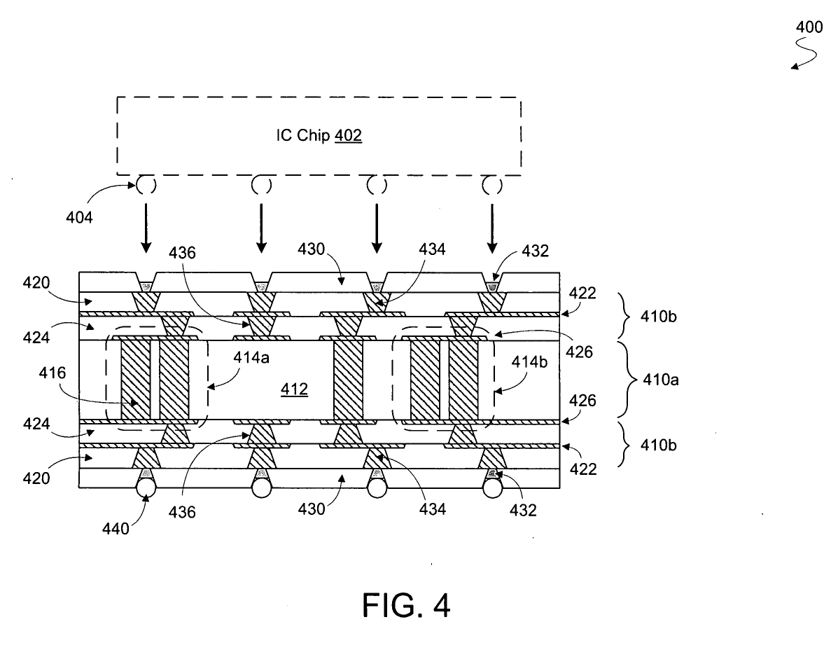

FIG. 4 is a cross-sectional view showing features of a semiconductor package 400 according to one embodiment. Package 400 may include some or all of the features of one of devices 100, 300 for example. In an embodiment, fabrication of package 400 includes one or more operations of method 200.

Package 400 may include a core portion 410a comprising, for example, one of substrates 110, 310. Although certain embodiments are not limited in this regard, core portion 410a may include multiple layers (not shown). Build-up portions 410b may be formed one or both sides of the core portion 410a—e.g., by laminating a predetermined number of layers in accordance with a build-up method. A semiconductor element, such as the illustrative IC chip 402, may be mounted on this semiconductor package 410, as illustrated with broken lines, via electrode terminals 404 (such as solder bumps or gold (Au) bumps) thereof.

Reference numeral 412 denotes one or more layers of an insulation material of core portion 410a, where through-holes variously extend through the one or more layers and extend to each of the build-up portions 410b. Reference numeral 416 denotes conductors deposited in such through-holes formed by core portion 410a. Reference numeral 426 denotes metal layers (e.g., inclusive of pads) formed on the insulation material 412 by patterning so as to be variously connected electrically to the conductors 416. Reference numeral 424 denotes other insulating layers (e.g., resin layers) formed on the metal layers 426 and on insulation material 412. Reference numeral 436 denotes via holes formed on the insulating layers 424 so as to variously reach pads of the metal layers 426. Reference numeral 422 denotes metal layers (e.g., inclusive of pads) formed on the insulating layers 424 by patterning so as to be filled inside the via holes 436. Reference numeral 420 denotes other insulating layers (e.g., resin layers) formed on the metal layers 422 and on the insulating layers 424. Other via holes may be formed on insulating layers 424 so as to variously extend to pads of metal layers 422. Reference numeral 434 denotes conductors variously filled in such via holes. Reference numeral 430 denotes solder resist layers which serve as protective layers (insulating layers) formed so as to cover surfaces of the insulating layers 420 other than portions thereof at conductors 434. Reference numeral 432 denotes nickel (Ni)/gold (Au) plated films formed on the conductors 434 and exposed by openings of the solder resist layers 430. Upon mounting the semiconductor chip 402 on package 400, the electrode terminals 404 thereof (such as the solder bumps) may be bonded to plated films 432 on the conductors 434 exposed from the openings of the solder resist layer 430 on an upper side. Reference numeral 440 denotes solder balls that provide for coupling of the lower one of build-up portions 410b to I/O contacts (not shown) included in, or to be coupled to, package 400.

In an embodiment, through-hole interconnects variously extending through core portion 410a include one or more sets of through-hole interconnects, wherein for each such set, the through-hole interconnects of the set are all redundant to one another. By way of illustration and not limitation, package 400 may include redundant through-hole interconnect pair 414a and/or redundant through-hole interconnect pair 414b. However, any of a variety of additional or alternative redundant interconnect structures may extend through core portion 410a, according to different embodiments.

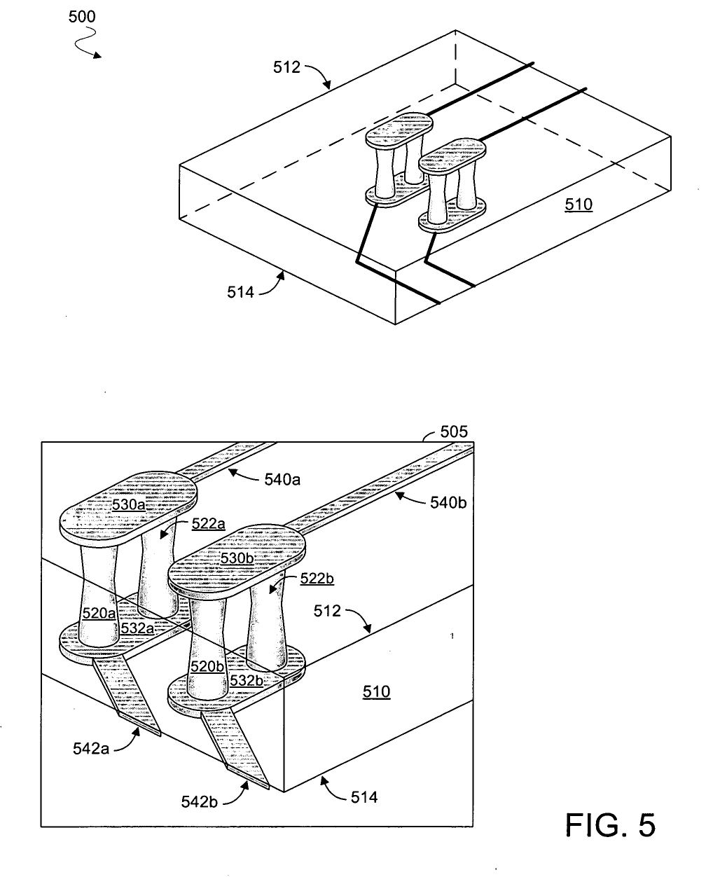

FIG. 5 shows features of a device 500 including through-hole interconnect structures according to an embodiment. Device 500 may include features of one of devices 100, 300 or features of package 400, for example. In one embodiment, fabrication of device 500 is performed according to method 200.

In the illustrative embodiment shown, device 500 includes a substrate 510 having formed therein multiple pairs of redundant through-hole interconnects. For example, as shown in detail view 505, one such redundant through-hole interconnect pair may include through-hole interconnects 520a, 522a each extending between opposite sides 512, 514 of substrate 510. Interconnect structures 530a, 532a may variously couple through-hole interconnects 520a, 522a to each other at respective ones of sides 512, 514. Another redundant through-hole interconnect pair of device 500 may include through-hole interconnects 520b, 522b, similarly extending between sides 512, 514. In an embodiment, interconnect structures 530b, 532b variously couple through-hole interconnects 520b, 522b to each other at respective ones of sides 512, 514.

An arrangement of through-hole interconnects in substrate 510 may facilitate efficient communication of differential signaling. For example, device 500 may further comprise trace portions 540a, 540b that are each to exchange a different respective one a differential signal pair. The pairs of redundant through-hole interconnects shown in detail view 505 may facilitate an exchange of the differential signal pair between sides 512, 514. For example, through-hole interconnects 520a, 522a may be coupled to exchange one signal of the differential signal pair between trace portion 540a and another trace portion 542a disposed on an opposite side of substrate 510. Similarly, through-hole interconnects 520b, 522b may be coupled to exchange the other signal of the differential signal pair between trace portion 540b and a trace portion 542b. In such an embodiment, interconnect structures 530a, 532a, 530b, 532b may be arranged to allow for relatively close positioning of trace portions 540a, 540b to each other and/or for relatively close positioning of trace portions 540a, 540b to each other.

For example, interconnect structures 530a, 532a may align with each other in a line that is parallel to (or at least not orthogonal to) a line of direction along which trace portion 540a extends to/from interconnect structures 530a, 532a. Alternatively or in addition, interconnect structures 530b, 532b may align with each other in a line that is at least not orthogonal to a line of direction along which trace portion 540b extends to/from interconnect structures 530b, 532b. In an embodiment interconnect structures 530a, 532a are aligned with each other along a line that is parallel with a line along which interconnect structures 530b, 532b are aligned. Such a configuration may allow for closer proximity of trace portions 540a, 540b to each other, thereby facilitating improved signal coupling by a differential signal pair.

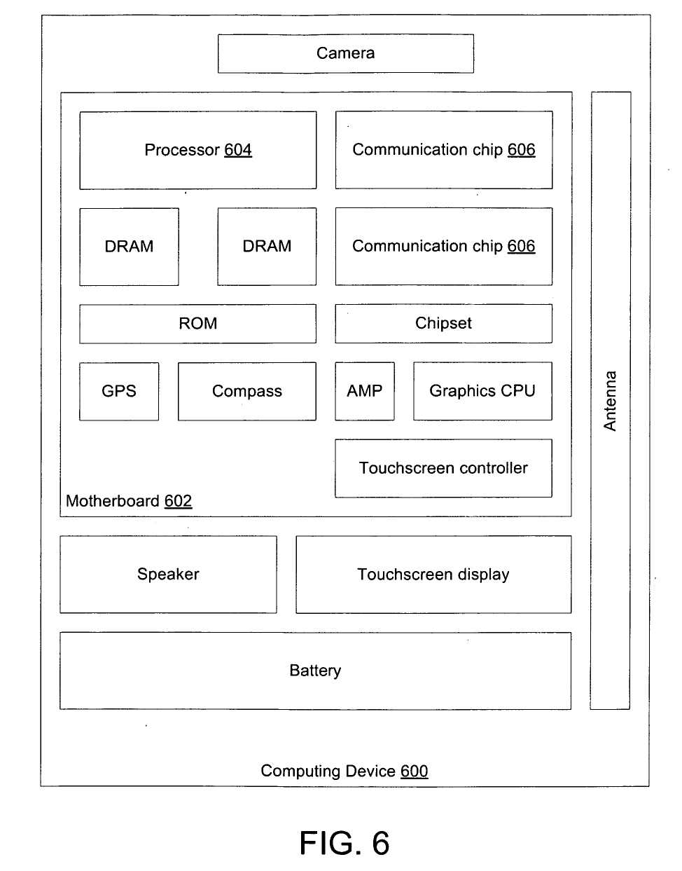

FIG. 6 illustrates a computing device 600 in accordance with one embodiment. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. The term “processor” may refer to any device or portion of a device that processes electronic data from registers and/or memory to transform that electronic data into other electronic data that may be stored in registers and/or memory. The communication chip 606 also includes an integrated circuit die packaged within the communication chip 606.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

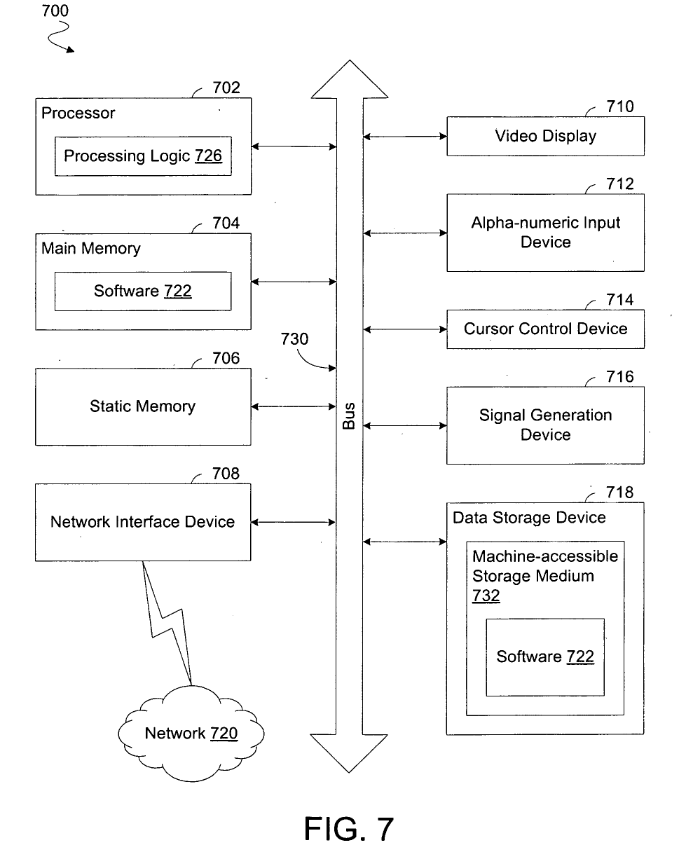

FIG. 7 illustrates a diagrammatic representation of a machine in the exemplary form of a computer system 700 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 700 includes a processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

Processor 702 represents one or more general-purpose processing devices such as a microprocessor, central processing unit, or the like. More particularly, the processor 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 702 may also be one or more special-purpose processing devices such as an application specific integrated circuit (ASIC), a field programmable gate array (FPGA), a digital signal processor (DSP), network processor, or the like. Processor 702 is configured to execute the processing logic 726 for performing the operations described herein.

The computer system 700 may further include a network interface device 708. The computer system 700 also may include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium (or more specifically a computer-readable storage medium) 732 on which is stored one or more sets of instructions (e.g., software 722) embodying any one or more of the methodologies or functions described herein. The software 722 may also reside, completely or at least partially, within the main memory 704 and/or within the processor 702 during execution thereof by the computer system 700, the main memory 704 and the processor 702 also constituting machine-readable storage media. The software 722 may further be transmitted or received over a network 720 via the network interface device 708.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

In one implementation, a device comprises a core including a substrate having formed therein a first through-hole and a second through-hole each extending from a first side of the substrate to a second side of the substrate, wherein an insulator is disposed between the first through-hole and the second through-hole in the substrate. The device further comprises a first through-hole interconnect disposed in the first through-hole, a second through-hole interconnect disposed in the second through-hole, a first interconnect structure to provide a short between the first through-hole interconnect and the second through-hole interconnect at the first side, and a second interconnect structure to provide a short between the first through-hole interconnect and the second through-hole interconnect at the second side, wherein a total volume of the first through-hole is equal to or less than twenty million (20·10⁶) cubic micrometers (μm³), and wherein a total volume of any voids formed by the first through-hole interconnect is equal to or more than 6·10³ μm³.

In an embodiment, the total volume of the first through-hole is equal to or less than thirteen million (13·10⁶) μm³. In another embodiment, the total volume of the first through-hole is equal to or less than three and a half million (3.5·10⁶) μm³. In another embodiment, a total volume of the second through-hole is equal to or less than twenty million (20·10⁶) μm³. In another embodiment, a thickness of the substrate between the first side and the second side is equal to or less than 400 μm. In another embodiment, a width of the first through-hole is equal to or less than 200 μm. In another embodiment, the width of the first through-hole is equal to or less than 100 μm.

In another embodiment, a total volume of any voids formed by the first through-hole interconnect is equal to or more than 9·10³ μm³. In another embodiment, the total volume of any voids formed by the first through-hole interconnect is in a range between 9·10³ μm³ and 17·10³ μm³. In another embodiment, a total volume of any voids formed by the second through-hole interconnect is equal to or more than 6·10³ μm³. In another embodiment, the substrate has further formed therein a third through-hole extending from the first side to the second side, and the device further comprises a third through-hole interconnect disposed in the third through-hole, wherein the first interconnect structure further provides a short between the third through-hole interconnect and one of the first through-hole interconnect and the second through-hole interconnect, and wherein the second interconnect structure further provides a short between the third through-hole interconnect and one of the first through-hole interconnect and the second through-hole interconnect.

In another embodiment, a first redundant through-hole interconnect pair of the device is configured to receive a first signal of a differential signal pair, the first redundant through-hole interconnect pair including the first through-hole interconnect and the second through-hole interconnect aligned with each other along a first line of direction, the device further comprises a second redundant through-hole interconnect pair aligned with each other in parallel with the first line of direction, the second redundant through-hole interconnect pair configured to receive a second signal of the differential signal pair. In another embodiment, the device further comprises a build-up layer disposed on the first side of the substrate.

In another implementation, a method comprises forming a first through-hole and a second through-hole each extending from a first side of a substrate to a second side of the substrate, wherein an insulator is disposed between the first through-hole and the second through-hole in the substrate, depositing a first conductor in the first through-hole, depositing a second conductor in the second through-hole, forming a first short between the first conductor and the second conductor at the first side, and forming a second short between the first conductor and the second conductor at the second side, wherein a total volume of the first through-hole is equal to or less than twenty million (20·10⁶) cubic micrometers (μm³), and wherein a total volume of any voids formed by the first through-hole interconnect is equal to or more than 6·103 μm³.

In an embodiment, the total volume of the first through-hole is equal to or less than thirteen million (13·10⁶) μm³. In another embodiment, the total volume of the first through-hole is equal to or less than three and a half million (3.5·10⁶) μm³. In another embodiment, a total volume of the second through-hole is equal to or less than twenty million (20·10⁶) μm³. In another embodiment, a thickness of the substrate between the first side and the second side is equal to or less than 400 μm. In another embodiment, a width of the first through-hole is equal to or less than 200 μm. In another embodiment, the width of the first through-hole is equal to or less than 100 μm. In another embodiment, a total volume of any voids formed by the first through-hole interconnect is equal to or more than 9·10³ μm³. In another embodiment, the total volume of any voids formed by the first through-hole interconnect is in a range between 9·10³ μm³ and 17·10³ In another embodiment, a total volume of any voids formed by the second through-hole interconnect is equal to or more than 6·10³ μm³.

In another implementation, a system comprises a packaged device including one or more integrated circuit (IC) chips, and a core including a substrate coupled to the one or more IC chips, the having formed therein a first through-hole and a second through-hole each extending from a first side of the substrate to a second side of the substrate, wherein an insulator is disposed between the first through-hole and the second through-hole in the substrate. The packaged device further comprises a first through-hole interconnect disposed in the first through-hole, a second through-hole interconnect disposed in the second through-hole, a first interconnect structure to provide a short between the first through-hole interconnect and the second through-hole interconnect at the first side, and a second interconnect structure to provide a short between the first through-hole interconnect and the second through-hole interconnect at the second side, wherein a total volume of the first through-hole is equal to or less than twenty million (20·10⁶) cubic micrometers (μm³), and wherein a total volume of any voids formed by the first through-hole interconnect is equal to or more than 6·10⁶ μm³. The system further comprises a display device coupled to the packaged device, the display device to display an image based on signals exchanged with the one or more IC chips.

In an embodiment, the total volume of the first through-hole is equal to or less than thirteen million (13·10⁶) μm³. In another embodiment, the total volume of the first through-hole is equal to or less than three and a half million (3.5·10⁶) μm³. In another embodiment, a total volume of the second through-hole is equal to or less than twenty million (20·10⁶) μm³. In another embodiment, a thickness of the substrate between the first side and the second side is equal to or less than 400 μm. In another embodiment, a width of the first through-hole is equal to or less than 200 μM. In another embodiment, the width of the first through-hole is equal to or less than 100 μm.

In another embodiment, a total volume of any voids formed by the first through-hole interconnect is equal to or more than 9·10³ μm³. In another embodiment, the total volume of any voids formed by the first through-hole interconnect is in a range between 9·10³ μm³ and 17·10³ μm³. In another embodiment, a total volume of any voids formed by the second through-hole interconnect is equal to or more than 6·10³ μm³. In another embodiment, the substrate has further formed therein a third through-hole extending from the first side to the second side, and the packaged device further comprises a third through-hole interconnect disposed in the third through-hole, wherein the first interconnect structure further provides a short between the third through-hole interconnect and one of the first through-hole interconnect and the second through-hole interconnect, and wherein the second interconnect structure further provides a short between the third through-hole interconnect and one of the first through-hole interconnect and the second through-hole interconnect.

In another embodiment, a first redundant through-hole interconnect pair of the packaged device is configured to receive a first signal of a differential signal pair, the first redundant through-hole interconnect pair including the first through-hole interconnect and the second through-hole interconnect aligned with each other along a first line of direction, the packaged device further comprises a second redundant through-hole interconnect pair aligned with each other in parallel with the first line of direction, the second redundant through-hole interconnect pair configured to receive a second signal of the differential signal pair. In another embodiment, the packaged device further comprising a build-up layer disposed on the first side of the substrate.

Techniques and architectures for providing interconnect structures in a substrate are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

1.-25. (canceled)

26. A device comprising:
a core including a substrate having formed therein a first through-hole and a second through-hole each extending from a first side of the substrate to a second side of the substrate, wherein an insulator is disposed between the first through-hole and the second through-hole in the substrate;
a first through-hole interconnect disposed in the first through-hole;
a second through-hole interconnect disposed in the second through-hole;
a first interconnect structure to provide a short between the first through-hole interconnect and the second through-hole interconnect at the first side; and
a second interconnect structure to provide a short between the first through-hole interconnect and the second through-hole interconnect at the second side;
wherein a total volume of the first through-hole is equal to or less than twenty million (20·10⁶) cubic micrometers (μm³), and wherein a total volume of any voids formed by the first through-hole interconnect is equal to or more than 6·10³ μm³.

27. The device of claim 26, wherein the total volume of the first through-hole is equal to or less than thirteen million (13·10⁶) μm³.

28. The device of claim 27, wherein the total volume of the first through-hole is equal to or less than three and a half million (3.5·10⁶) μm³.

29. The device of claim 26, wherein a total volume of the second through-hole is equal to or less than twenty million (20·10⁶) μm³.

30. The device of claim 26, wherein a thickness of the substrate between the first side and the second side is equal to or less than 400 μm.

31. The device of claim 26, wherein a width of the first through-hole is equal to or less than 200 μm.

32. The device of claim 31, wherein the width of the first through-hole is equal to or less than 100 μm.

33. The device of claim 26, wherein a total volume of any voids formed by the first through-hole interconnect is equal to or more than 9·10³ μm³.

34. The device of claim 26, wherein the total volume of any voids formed by the first through-hole interconnect is in a range between 9·10³ μm³ and 17·10³ μm³.

35. The device of claim 26, wherein a total volume of any voids formed by the second through-hole interconnect is equal to or more than 6·10³ μm³.

36. The device of claim 26, the substrate having further formed therein a third through-hole extending from the first side to the second side, the device further comprising:
a third through-hole interconnect disposed in the third through-hole;
wherein the first interconnect structure further provides a short between the third through-hole interconnect and one of the first through-hole interconnect and the second through-hole interconnect; and
wherein the second interconnect structure further provides a short between the third through-hole interconnect and one of the first through-hole interconnect and the second through-hole interconnect.

37. The device of claim 26, wherein a first redundant through-hole interconnect pair of the device is configured to receive a first signal of a differential signal pair, the first redundant through-hole interconnect pair including the first through-hole interconnect and the second through-hole interconnect aligned with each other along a first line of direction, the device further comprising a second redundant through-hole interconnect pair aligned with each other in parallel with the first line of direction, the second redundant through-hole interconnect pair configured to receive a second signal of the differential signal pair.

38. The device of claim 26, further comprising a build-up layer disposed on the first side of the substrate.

39. A method comprising:
forming a first through-hole and a second through-hole each extending from a first side of a substrate to a second side of the substrate, wherein an insulator is disposed between the first through-hole and the second through-hole in the substrate;
depositing a first conductor in the first through-hole;
depositing a second conductor in the second through-hole;
forming a first short between the first conductor and the second conductor at the first side; and
forming a second short between the first conductor and the second conductor at the second side;
wherein a total volume of the first through-hole is equal to or less than twenty million (20·10⁶) cubic micrometers (μm³), and wherein a total volume of any voids formed by the first through-hole interconnect is equal to or more than 6·10³ μm³.

40. The method of claim 39, wherein the total volume of the first through-hole is equal to or less than thirteen million (13·10⁶) μm³.

41. The method of claim 40, wherein the total volume of the first through-hole is equal to or less than three and a half million (3.5·10⁶) μm³.

42. The method of claim 39, wherein a total volume of the second through-hole is equal to or less than twenty million (20·10⁶) μm³.

43. The method of claim 39, wherein a thickness of the substrate between the first side and the second side is equal to or less than 400 μm.

44. A system comprising:
a packaged device including:
one or more integrated circuit (IC) chips;
a core including a substrate coupled to the one or more IC chips, the having formed therein a first through-hole and a second through-hole each extending from a first side of the substrate to a second side of the substrate, wherein an insulator is disposed between the first through-hole and the second through-hole in the substrate;
a first through-hole interconnect disposed in the first through-hole;
a second through-hole interconnect disposed in the second through-hole;
a first interconnect structure to provide a short between the first through-hole interconnect and the second through-hole interconnect at the first side; and
a second interconnect structure to provide a short between the first through-hole interconnect and the second through-hole interconnect at the second side;
wherein a total volume of the first through-hole is equal to or less than twenty million (20·10⁶) cubic micrometers (μm³), and wherein a total volume of any voids formed by the first through-hole interconnect is equal to or more than 6·10³ μm³; and
a display device coupled to the packaged device, the display device to display an image based on signals exchanged with the one or more IC chips.

45. The system of claim 44, wherein the total volume of the first through-hole is equal to or less than thirteen million (13·10⁶) μm³.

46. The system of claim 44, wherein a total volume of the second through-hole is equal to or less than twenty million (20·10⁶) μm³.

47. The system of claim 44, wherein the total volume of any voids formed by the first through-hole interconnect is in a range between 9·10³ μm³ and 17·10³ μm³.

48. The system of claim 44, wherein a total volume of any voids formed by the second through-hole interconnect is equal to or more than 6·10³ μm³.
